(19) United States
(12) Patent Application Publication
(10) Pub. No.: US 2011/0049334 A1
(43) Pub. Date: Mar. 3, 2011

(54) OPTICAL MODULE

(75) Inventors: Hideyuki Nasu, Tokyo (JP); Yozo Ishikawa, Tokyo (JP)

(73) Assignee: FURUKAWA ELECTRIC CO., LTD., Tokyo (JP)

(21) Appl. No.: 12/863,194

(22) PCT Filed: Jan. 15, 2009
(86) PCT No.: PCT/JP2009/050448

§ 371 Date: Nov. 12, 2010

(30) Foreign Application Priority Data
Jan. 16, 2008 (JP) 2008-007442
Jan. 16, 2008 (JP) 2008-007443

(51) Int. Cl. G02B 6/122; H01L 31/102; H03F 3/08

(52) U.S. Cl. 250/208.2; 385/14

(57) ABSTRACT

An optical module transmits optical signals through a plurality of optical fibers in parallel. The optical module includes a substrate including an electrode pattern, a plurality of optical elements mounted on the electrode pattern of the substrate, and an electronic device mounted on the electrode pattern of the substrate and electrically connected to the optical elements. The optical elements and the electronic device are arranged on the substrate close to each other such that lengths of a plurality of transmission lines each transmitting a signal between each of the optical elements and the electronic device are minimized.

### TECHNICAL FIELD

The present invention relates to an optical module, and more particularly, to an optical module as a parallel optical transmission module for an inter-board optical transmission system and an inter-apparatus (inter-housing) optical transmission system, which performs a parallel transmission of optical signals with a plurality of optical fibers (channels) arranged in parallel.

### BACKGROUND ART

An optical module including a plurality of light emitting elements integrated with an electronic device (i.e., an integrated circuit (IC)) driving the light emitting elements in a case has been known (see, for example, Patent Document 1).

Furthermore, an optical module including a plurality of laser diodes or a plurality of photodiodes integrated with an IC (a driver IC driving the laser diodes or an amplifier IC processing outputs of the photodiodes) in a case has been known (see, for example, Non-Patent Document 1).

Patent Document 1: Japanese Patent Application Laid-Open No. 2002-261372

Non-Patent Document 1: Toshiyuki Okayasu, “High-Density Interconnection in Memory Test System”, 2nd Silicon Analog RF Study Meeting, Aug. 2, 2004

### DISCLOSURE OF INVENTION

### Problems to be Solved by the Invention

In the conventional optical modules disclosed in Patent Document 1 and Non-Patent Document 1, a center of each of the optical fibers held by a ferrule is aligned with a center of a light emitting section of each of the optical elements by a passive alignment using a silicon optical bench (SiOB). In this configuration, because the SiOB intervenes between the optical elements and the electronic device (IC), the optical elements are electrically connected to the electronic device via a line pattern formed on the SiOB. Specifically, the optical elements are connected to the line pattern on the SiOB in a wired manner, and the line pattern is then connected to the electronic device in a wired manner. This causes a plurality of transmission lines electrically connecting the light emitting elements and the electronic device to increase in length. Consequently, a crosstalk component between adjacent transmission lines increases, causing a problem in realizing a high-speed parallel optical transmission.

The present invention has been devised in view of such a conventional problem, and it is an object of the present invention to provide an optical module with a reduced crosstalk component to realize a high-speed parallel optical transmission.

### Means for Solving the Problems

To solve the above problems, an optical module according to the invention of claim 1 is an optical module that transmits optical signals with a plurality of optical fibers in parallel. The optical module includes a substrate having an electrode pattern, a plurality of optical elements mounted on the electrode pattern of the substrate, and an electronic device mounted on the electrode pattern of the substrate and electrically connected to the optical elements. The optical elements and the electronic device are arranged on the substrate in such a manner that lengths of a plurality of transmission lines to transmit signals between the optical elements and the electronic device are minimized.

According to this configuration, a crosstalk between adjacent transmission lines can be reduced, and as a result, a high speed parallel optical transmission can be realized.

An optical module of the invention according to claim 2 is the optical module according to claim 1 further including an optical connector unit that holds the optical fibers and is fixed on the substrate at a position where the optical fibers and the optical elements are optically coupled to each other, respectively. The position of the optical connector unit can two-dimensionally be adjusted on a plane of the substrate.

According to this configuration, an active alignment is performed in such a manner that the optical fibers and the optical elements are optically coupled to each other, respectively, by two-dimensionally adjusting the position of the optical connector unit on the plane of the substrate. Consequently, unlike the conventional technique, the SiOB used in the passive alignment becomes unnecessary, and the optical elements and the electronic device can be arranged at positions on the substrate close to each other. Therefore, the lengths of the transmission lines electrically connecting the light emitting elements and the electronic device can be shortened. In addition, “a position where the optical fibers and the optical elements are optically coupled to each other, respectively” means the position where the center (core center) of a facet of each of the optical fibers and the center of each light emitting section or each light receiving section of the optical elements are aligned with each other.

An optical module of the invention according to claim 3 features that the substrate includes a recess section formed thereon, the electronic device is arranged in the recess section formed on the substrate in such a manner that surfaces of the optical elements and a surface of the electronic device are substantially on the same level, and the surfaces of the optical elements and the surface of the electronic device are electrically connected to each other in a direct manner with a plurality of wires as the transmission lines.

According to this configuration, the crosstalk between adjacent wires can be reduced in the optical module in which the optical elements and the electronic device are mounted by a wire bonding.

An optical module of the invention according to claim 4 features that the recess section has substantially vertical wall surfaces. The optical elements are arranged on the substrate along one of the wall surfaces at a position close to the one of the wall surfaces, and the electronic device is arranged in the recess section at a position close to the one of the wall surfaces.

According to this configuration, because the optical elements and the electronic device can be arranged close to each other, the lengths of the transmission lines can furthermore be shortened. Therefore, the crosstalk between adjacent transmission lines can be further reduced, and as a result, the high speed parallel optical transmission can be realized.

An optical module of the invention according to claim 5 features that the electronic device is mounted on the substrate by a flip chip mounting, the optical elements are arranged in a recess section formed on the substrate in such a manner that surfaces of the optical elements and a surface of the substrate are substantially on a same level, and the optical elements and a wiring on the substrate, to which wiring the electronic device is electrically connected, are electrically connected to each other with a plurality of wires.

According to the configuration, crosstalk between adjacent transmission lines can be reduced in the optical module in which the electronic device is mounted on the substrate by the flip chip mounting. In addition, the transmission lines for transmitting signals between the optical elements and the electronic device are composed of the wiring on the substrate to which the electronic device is electrically connected and the wires in this case.

An optical module of the invention according to claim 6 features that the optical elements are surface emitting semiconductor laser elements to severally emit a light from back surface side thereof, the optical elements are mounted on the substrate by flip chip mounting, the electronic device is arranged in a recess section formed on the substrate in such a manner that a surface of the electronic device and a surface of the substrate are substantially on a same level to minimize wire lengths, and the electronic device and a wiring on the substrate to which the optical elements are electrically connected are electrically connected to each other with a plurality of wires.

According to the configuration, crosstalk between adjacent transmission lines can be reduced in the optical module mounting the optical elements on the substrate by the flip chip mounting, each of which optical elements is a surface emitting semiconductor laser element (back surface light emitting type VCSEL). In addition, in this case, the transmission lines transmitting signals between the optical elements and the electronic device are composed of the wiring on the substrate to which the optical elements are electrically connected and the wires.

An optical module of the invention according to claim 7 features that the electronic device is arranged in a recess section formed on the substrate, surfaces of the optical elements and a surface of the electronic device are electrically connected to each other with a plurality of wires as the transmission lines in a direct manner, and the surface of the electronic device is set to be higher than the surfaces of the optical elements within a range in which no electrical short circuits are caused at respective both ends of the wires.

According to the configuration, each of the wire lengths can be shortened as short as possible without causing any electrical short circuit at each of both the ends of the wires.

An optical module of the invention according to claim 8 features that the electronic device is arranged in a recess section formed on the substrate, surfaces of the optical elements and a surface of the electronic device are electrically connected to each other with a plurality of wires as the transmission lines in a direct manner, and the surfaces of the optical elements are set to be higher than the surface of the electronic device within a range in which no electrical short circuits are caused at respective both ends of the wires.

According to the configuration, each of the wiring lengths can be shortened as short as possible without causing any electrical short circuit at each of both the ends of the wires.

An optical module of the invention according to claim 9 features that the optical module includes a plurality of surface emitting semiconductor laser elements as the optical elements and a driver IC as the electronic device, which driver IC drives the surface emitting semiconductor laser elements, and the optical module is configured as a transmission side optical module to transmit the optical signals to be emitted from the surface emitting semiconductor laser elements, respectively, to an outside through the optical fibers in parallel.

According to the configuration, the transmission side optical module capable of performing high speed parallel optical transmission can be realized.

An optical module of the invention according to claim 10 features that the optical module includes a plurality of photodiodes as the optical elements and an amplifying IC as the electronic device, which amplifying IC has a function to convert output currents of the photodiodes into voltages to amplify the voltage, and the optical module is configured as a reception side optical module to receive the optical signals, which are parallelly transmitted from an outside through the optical fibers, with the photodiodes to convert the received optical signals into electric signals.

According to the configuration, the reception side optical module capable of performing high speed parallel optical transmission can be realized.

In order to solve the above problem, an optical module of the invention according to claim 11 is an optical module to parallelly transmit optical signals with a plurality of optical fibers, the optical module including a substrate having an electrode pattern, a plurality of optical elements which are mounted on the electrode pattern of the substrate, and an electronic device which is mounted on the electrode pattern of the substrate and which is electrically connected to the optical elements, wherein the optical elements and the electronic device are arranged at positions close to each other on the substrate. According to the configuration, the lengths of a plurality of transmission lines electrically connecting the light emitting elements and the electronic device is shortened, and crosstalk between adjacent transmission lines can be reduced. Hereby, high speed parallel optical transmission can be realized.

An optical module of the invention according to claim 12 further includes an optical connector unit that holds the optical fibers and is fixed on the substrate at a position where the optical fibers and the optical elements are optically coupled to each other, respectively, and a position of the optical connector unit can two-dimensionally be adjusted on the substrate. According to the configuration, the configuration is the one performing the active alignment in order that the optical fibers and the optical elements are optically coupled to each other, respectively, by performing two-dimensional position adjustment of the optical connector unit on the substrate. Consequently, the SiOB for performing the passive alignment becomes unnecessary unlike the conventional technique, and the optical elements and the electronic device can be arranged at positions close to each other on the substrate. Hereby, the lengths of the transmission lines electrically connecting the light emitting elements and the electronic device can be shortened. In addition, “a position where the optical fibers and the optical elements are optically coupled to each other, respectively” indicates the position where the center (core center) of each one end of the optical fibers and the center of each light emitting section or each light receiving section of the optical elements are aligned with each other, respectively.

An optical module of the invention according to claim 13 features that the electronic device and the optical elements are electrically connected to each other in a direct manner, respectively, with a plurality of wires. According to the configuration, the wire lengths of the wires connecting the light emitting elements and the electronic device electrically become short. Hereby, crosstalk between adjacent wires can be reduced in the optical module in which the electronic device and the optical elements are mounted by wire bonding mounting.

An optical module of the invention according to claim 14 features that each of lengths in horizontal directions of the wires is set to be 500 micrometers or less. According to the configuration, the crosstalk between adjacent wires (channels) at the time of the transmission at the rate of 10 Gbit/s (<8 GHz) can be suppressed to be 30 decibels or less.

An optical module of the invention according to claim 15 features that the electronic device is mounted on the substrate by flip chip mounting, and the optical elements and a wiring on the substrate to which the electronic device is electrically connected are electrically connected to each other, respectively, with a plurality of wires. According to the configuration, a plurality of transmission lines are composed of the wires and the wiring, respectively, which wires and wiring electrically connect the optical elements and the electronic device to each other, respectively, and consequently the lengths of the transmission lines become short. Hereby, crosstalk between adjacent transmission lines can be reduced in the optical module including the electronic device mounted on the substrate by the flip chip mounting.

An optical module of the invention according to claim 16 features that lengths of a plurality of transmission lines composed of the wires and the wiring, which wires and wiring electrically connect the optical elements and the electronic device, respectively, are set to be 500 micrometers or less. According to the configuration, the crosstalk between adjacent wires (channels) at the time of the transmission at the rate of 10 Gbit/s (<8 GHz) can be suppressed to be 30 decibels or less.

An optical module of the invention according to claim 17 features that the optical module is configured as a transmission side optical module to include a plurality of surface emitting semiconductor laser elements as the optical elements and a driver IC as the electronic device to drive the surface emitting semiconductor laser elements, which transmission side optical module parallelly transmits optical signals emitted from the surface emitting semiconductor laser elements, respectively, to an outside through the optical fibers. According to the configuration, the transmission side optical module capable of high speed parallel optical transmission can be realized.

An optical module of the invention according to claim 18 features that the optical module is an amplifying integrated circuit that converts output currents of the photodiodes into voltages and amplifies the voltages, and the optical module is a reception side optical module that receives optical signals from an outside through the optical fibers in parallel, and converts the received optical signals into electric signals with the photodiodes. According to the configuration, the reception side optical module capable of high speed parallel optical transmission can be realized.

### EFFECTS OF THE INVENTION

According to the present invention, a high speed parallel optical transmission can be realized by reducing a crosstalk component.

### BRIEF DESCRIPTION OF DRAWINGS

FIG. 1 is a perspective view of an optical module according to a first embodiment of the present invention showing its main part.

FIG. 2 is a cross section of the main part shown in FIG. 1.

FIG. 3 is a longitudinal cross section of the module according to the first embodiment showing its overall structure.

FIG. 4A is a perspective view showing the whole optical module according to the first embodiment.

FIG. 4B is an enlarged view of an optical fiber.

FIG. 4C is a plan view of the main part showing a connection relation between each surface emitting semiconductor laser element of a laser diode array and a driver IC.

FIG. 5 is an exploded perspective view showing the optical module of the first embodiment.

FIG. 6 is a perspective view showing an optical connector unit of the optical module.

FIG. 7 is a perspective view showing a state in which an external connector is mounted on the optical connector unit.

FIG. 8 is a perspective view showing the principal part of an optical module according to a second embodiment.

FIG. 9 is a sectional view according to the principal part of an optical module according to a third embodiment.

FIG. 10 is a sectional view showing the principal part of an optical module according to a fourth embodiment.

FIG. 11 is a sectional view showing the principal part of an optical module according to a fifth embodiment.

FIG. 12 is an explanatory view of an example of a sixth embodiment.

FIG. 13 is a graph showing comparisons of crosstalk between adjacent channels of a conventional model and a proposed model.

### BEST MODE FOR CARRYING OUT THE INVENTION

Exemplary embodiments of the present invention are described in detail below with reference to accompanying drawings. In descriptions of the embodiments, similar parts are assigned with the same reference numerals, and overlapped explanations thereof are omitted.

### First Embodiment

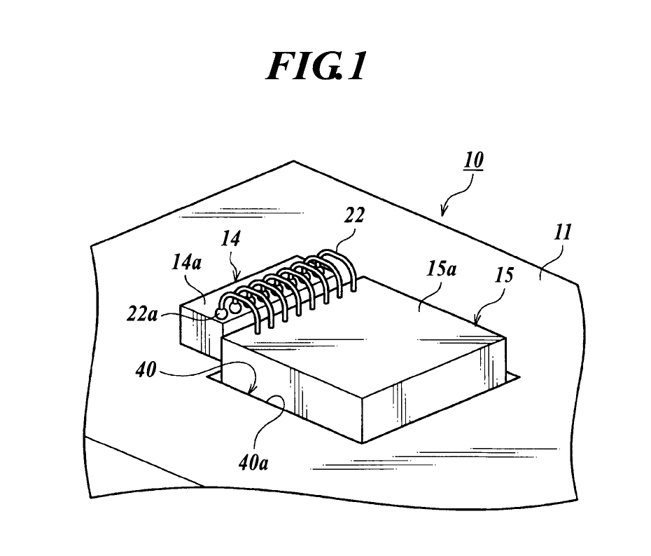

An optical module according to a first embodiment of the present invention is described with reference to FIGS. 1 to 7.

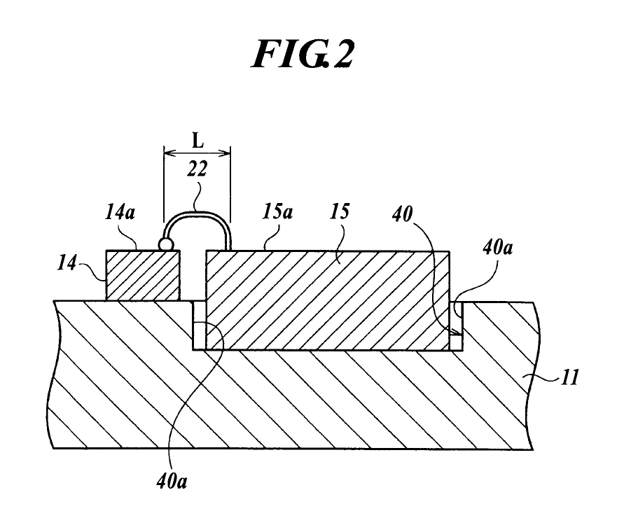

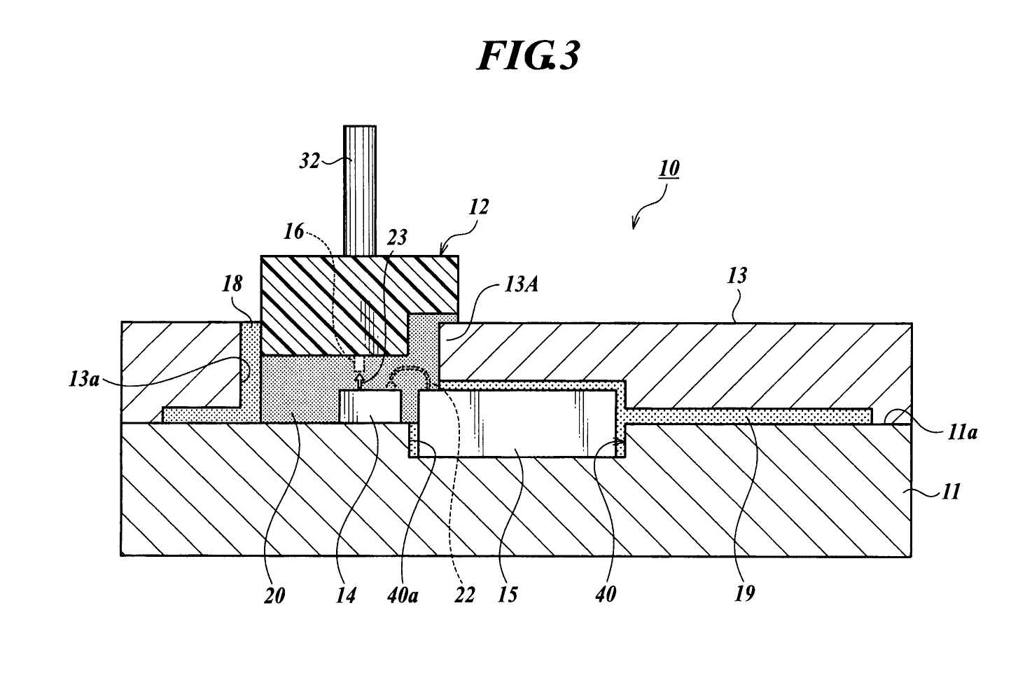

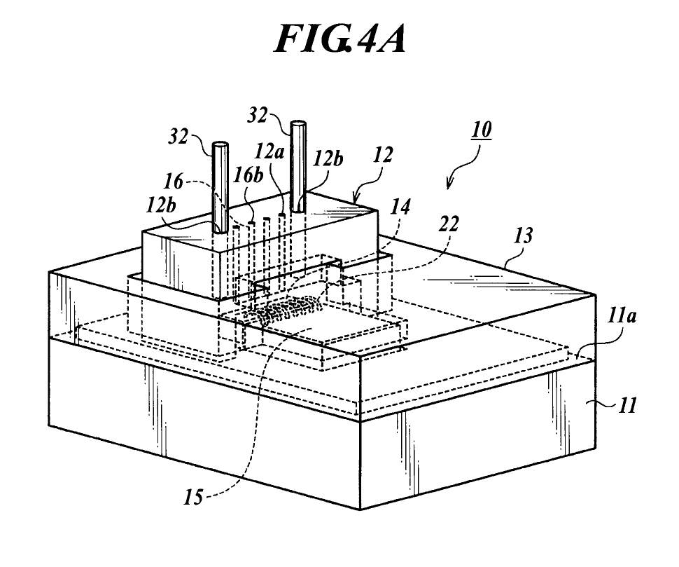

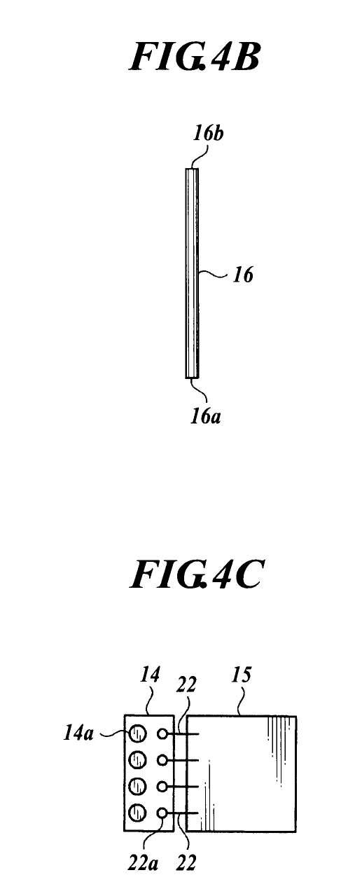

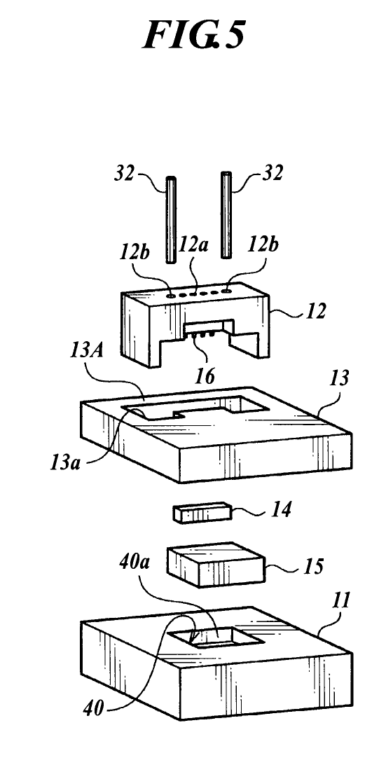

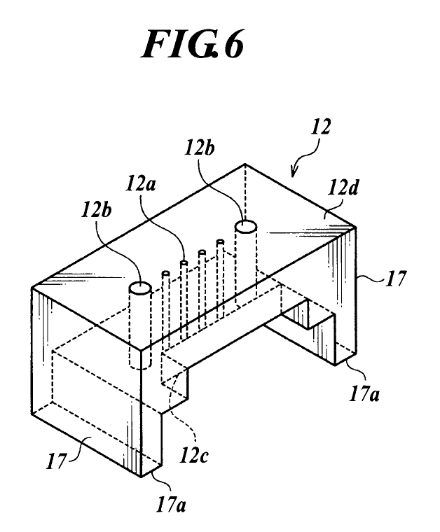

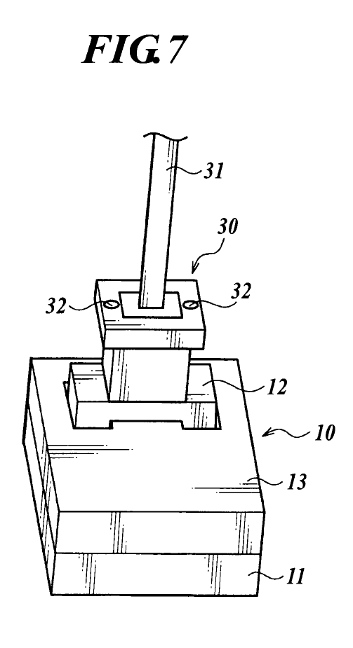

FIG. 1 is a perspective view of the optical module according to the first embodiment showing its main part, and FIG. 2 is a cross section of the main part shown in FIG. 1. FIG. 3 is a longitudinal cross section of the optical module showing its overall structure. FIG. 4A is a perspective view of the whole optical module, FIG. 4B is an enlarged view of one of a plurality of optical fibers used in the optical module, and FIG. 4C is a plan view of the main part showing a connection relation between each surface emitting semiconductor laser element of a laser diode array and a driver IC in the optical module. FIG. 5 is an exploded perspective view of the optical module showing its overall structure, FIG. 6 is a perspective view of an optical connector unit of the optical module, and FIG. 7 is a perspective view of the optical module showing a state in which an external connector (multicore ferrule type connector) is mounted on the optical connector unit.

The optical module 10 according to the first embodiment is an optical module that transmits optical signals with a plurality of optical fibers in parallel. As shown in FIGS. 1 and 2, the optical module 10 includes a substrate 11 having an electrode pattern (not shown), a plurality of optical elements mounted on the electrode pattern in an aligned manner, and an electronic device mounted on the electrode pattern and electrically connected to the optical elements.

The substrate 11 is made of ceramic. In the present embodiment, the optical elements are composed of a laser diode array 14 including a plurality of surface emitting semiconductor laser elements (optical elements) arrayed in a line. A reference numeral 14a in FIG. 4C denotes one of light emitting sections (aperture sections) of each of the surface emitting semiconductor laser elements of the laser diode array 14. The surface emitting semiconductor laser element as optical elements are vertical cavity surface emitting lasers (VCSELs) each emitting a light (an optical signal 23) in a direction perpendicular to a substrate surface. The electronic device is a driver IC 15 driving the surface emitting semiconductor laser elements of the laser diode array 14.

A feature of the optical module 10 is that the laser diode array 14 and the driver IC are arranged on the substrate 11 in such a manner that lengths of a plurality of wires (transmission lines) 22 each transmitting a signal between each of the surface emitting semiconductor laser elements of the laser diode array 14 and the driver IC 15 are minimized, as shown FIGS. 1 and 2. Specifically, the driver IC 15 is arranged in a recess section 40 formed on the substrate 11 in such a manner that a surface (face) 14a of the laser diode array 14 and a surface (face) 15a of the driver IC 15 are substantially on the same level to minimize the lengths of the wires.

Furthermore, in the optical module 10, wall surfaces 40a of the recess section 40 are formed to be substantially vertical with respect to the substrate surface to arrange the laser diode array 14 and the driver IC 15 close to each other so that the lengths of the wires 22 are minimized. The laser diode array 14 is arranged on the substrate 11 at a position close to one of the wall surfaces 40a, and the driver IC 15 is arranged at a position in the recess section 40 close to the wall surface 40a.

The laser diode array 14 is mounted on a surface 11a of the substrate 11 by being adhered thereon with, for example, a die attach adhesive. The driver IC 15 is mounted on a bottom surface of the recess section 40 by being adhered thereon with, for example, the die attach adhesive, with a part of the driver IC 15 housed in the recess section 40 of the substrate 11. The recess section 40 is a rectangular pit having the substantially vertical wall surfaces 40a. The laser diode array 14 is arranged on the surface 11a of the substrate in such a manner that its end surface comes close to the wall surface 40a. On the other hand, the driver IC 15 is arranged on the bottom surface of the recess section 40 in such a manner that its end surface comes close to the wall surface 40a. In this manner, the laser diode array 14 and the driver IC 15 are arranged on the substrate 11 at the positions close to each other. After that, the driver IC 15 and the surface emitting semiconductor laser elements of the laser diode array 14, i.e., electrodes on a surface 15a of the driver IC 15 and electrodes of the surface emitting semiconductor laser elements on the surface 14a of the laser diode array 14, are electrically connected in a direct manner with the wires 22 as the transmission lines (see, FIGS. 1, 2, and 4C).

Namely, the driver IC 15 and the surface emitting semiconductor laser elements of the laser diode array 14 are electrically connected to each other with the wires 22 without any wiring on an SiOB, unlike the conventional technique described above. With this configuration, a modulation signal is input from the driver IC 15 to each of the surface emitting semiconductor laser elements of the laser diode array 14 through each of the wires 22, and the optical signal 23 modulated by the modulation signal is emitted from each of the surface emitting semiconductor laser elements of the laser diode array 14. The driver IC 15 and the electrode pattern of the substrate 11 are also electrically connected to each other with a plurality of bonding wires (not shown). A reference numeral 22a in FIG. 4C denotes a ball formed on the electrode of each of the surface emitting semiconductor laser elements.

The optical module 10 further includes an optical connector unit 12, a cover 13, and two guide pins 32 as shown in FIGS. 3, 4A, and 5.

The optical connector unit 12 holds a plurality of optical fibers 16, aligned in a line (in a direction normal to a plane of the paper in FIG. 3), as shown in FIGS. 4A to 4C and 6. The optical connector unit 12 is aligned by the active alignment in such a manner that the center (core center) of each of first facets 16a (see FIG. 4B) of the optical fibers 16 and the center of each of the light emitting sections 14a of the laser diode array 14 are aligned with each other. After that, the optical connector unit 12 is fixed on the surface 11a of the substrate 11. With this configuration, a light (optical signal 23) emitted from each of the light emitting sections 14a of the laser diode array 14 is optically coupled to the first facet 16a of a corresponding one of the optical fibers 16.

The optical connector unit 12 further includes side wall sections 17 on both sides as shown in FIG. 6. Bottom surfaces 17a of the side wall sections 17 make contact with the surface 11a of the substrate 11 in a slidable manner. The optical connector unit 12 is two-dimensionally moved on of plane of the surface 11a of the substrate 11 by the active alignment such that the center of each of the first facets 16a of the optical fibers 16 and the center of each of the light emitting sections 14a of the laser diode array 14 are aligned with each other, and after that, the bottom surfaces 17a of the side wall sections 17 of the optical connector unit 12 are fixed to the surface 11a of the substrate 11 using an adhesive or the like.

As shown in FIG. 6, the optical connector unit 12 further includes a plurality of fiber holding holes 12a aligned in a line, into which the optical fibers 16 are fitted, respectively, and two guide pin holes 12b provided at both sides of the fiber holding holes 12a in an array direction. The two guide pins 32 are configured to fit into the two guide pin holes 12b.

The two guide pins 32 are configured to fit into two through-holes, respectively, of a multicore optical fiber connector (hereinafter, “an MT connector”) 30, shown in FIG. 7, which is an external connector. By fitting the two guide pins 32 into the two through-holes of the MT connector 30, respectively, the MT connector 30 is mounted on the optical connector unit 12, as shown in FIG. 7, in a state in which the center (core center) of each of the optical fibers of a multicore optical fiber (multicore tape optical fiber) 31 held by the MT connector 30 and each of the centers (core centers) of the optical fibers 16 held by the optical connector unit 12 are aligned with each other.

As shown in FIGS. 3, 4A, and 5, the cover 13 includes an opening 13a for mounting the optical connector unit 12, and is fixed to the substrate 11 using an adhesive or the like to cover all the parts including the laser diode array 14 and the driver IC 15. The cover 13 is made of a material having high thermal conductivity, such as an alloy of copper (Cu) and tungsten (W).

Furthermore, a resin 18, such as a resin sealing agent or an adhesive, is filled in a space between a side surface of the optical connector unit 12 and the opening 13a of the cover 13 as shown in FIG. 3. A silicone gel 19, having heat conductance and insulation properties, is filled in a gap (space) between the driver IC 15 and the cover 13 as a sealing agent. Furthermore, a transparent silicone gel 20 is filled in the space between each of the first facets 16a of the optical fibers 16 and each of the light emitting sections 14a of the laser diode array 14 as a sealing agent.

The first embodiment configured as described above has following operations and effects.
The laser diode array 14 and the driver IC are arranged on the substrate 11 in such a manner that the lengths of the wires (transmission lines) 22 for transmitting signals between the surface emitting semiconductor laser elements of the laser diode array 14 and the driver IC 15 are minimized. Therefore, a crosstalk between adjacent ones of the wires 22 can be reduced, and a high speed parallel optical transmission can be realized.
Because the driver IC 15 is arranged in the recess section 40 such that the surface (face) 14a of the laser diode array 14 and the surface (face) 15a of the driver IC 15 are substantially on the same level to minimize the lengths of the transmission lines and the surface 14a and the surface (face) 15a are electrically connected to each other in a direct manner with the wires 22 as the transmission lines, wire lengths L of the wires 22 (see FIG. 2) are shortened. Therefore, the crosstalk between adjacent ones of the wires 22 can be reduced in the optical module in which the laser diode array 14 and the driver IC 15 are mounted by the wire bonding.
The optical fibers 16 and the surface emitting semiconductor laser elements of the laser diode array 14 are optically coupled to each other, respectively, by the active alignment by performing a two-dimensional position adjustment of the optical connector unit 12 on the plane of the substrate 11. Namely, by the active alignment, the center of each of the first facets 16a of the optical fibers 16 and the center of each of the light emitting sections 14a of the laser diode array 14 are aligned with each other. Consequently, unlike the conventional technique described above, the SiOB for performing the passive alignment becomes unnecessary, and the laser diode array 14 and the driver IC 15 can be arranged on the substrate 11 at positions close to each other. Therefore, the wire lengths L of the wires 22 electrically connecting the surface emitting semiconductor laser elements of the laser diode array 14 and the driver IC 15 can be shortened, and the crosstalk between adjacent ones of the wires 22 can be reduced.
Because the wall surfaces 40a of the recess section 40 are formed to be substantially vertical, the laser diode array 14 and the driver IC 15 can be arranged to be close to each other, and the wires 22 can be shortened. Hereby, crosstalk between adjacent ones of the wires 22 can be reduced, and high speed parallel optical transmission can be realized.

### Second Embodiment

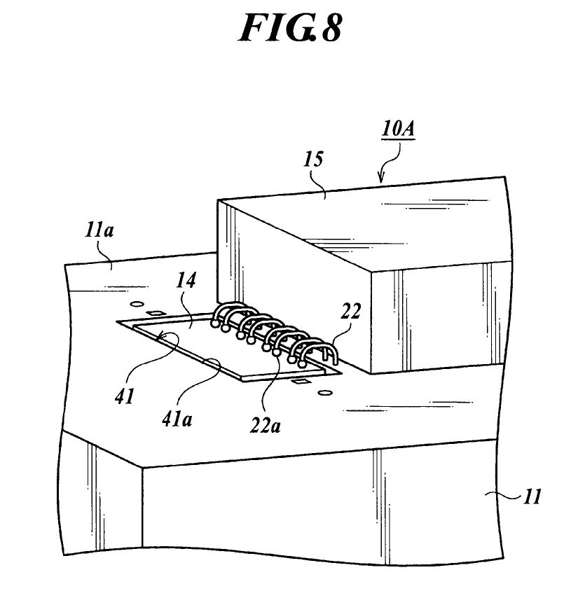

An optical module 10A according to a second embodiment is described with reference to FIG. 8.

In the first embodiment described above, the driver IC 15 is mounted on the electrode pattern of the substrate 11 by the wire bonding. On the other hand, the features of the optical module 10A according to the second embodiment exist in the following configuration.
As shown in FIG. 8, the driver IC 15 is mounted on the electrode pattern of the substrate 11 by the flip chip mounting.
The laser diode array 14 is arranged in a recess section 41 formed on the substrate 11 in order that the surface 14a of the laser diode array 14 and the surface 11a of the substrate 11 are substantially on a same level to minimize the wire lengths.
The surface emitting semiconductor laser elements of the laser diode array 14 and the wiring on the substrate 11 to which the driver IC 15 is electrically connected are connected to each other with the wires 22.

The other configuration is similar to that of the optical module 10 of the first embodiment described above.

By such a configuration, the lengths of the wires (transmission lines) 22 for transmitting signals between the surface emitting semiconductor laser elements of the laser diode array 14 and the driver IC 15, respectively, are minimized.

The whole of the laser diode array 14 is housed in the recess section 41 of the substrate 11 and is mounted on the bottom surface of the recess section 41 by, for example, being adhered with a die attach adhesive. The recess section 41 is a rectangular hole having substantially vertical wall surfaces 41a and substantially the same depth as the height of the laser diode array 14. The laser diode array 14 is arranged in the recess section 41 in such a way that one of the end faces thereof becomes close to one of the wall surfaces 41a. On the other hand, the driver IC 15 is mounted on the electrode pattern of the substrate 11 in such a way that one of the end faces of the driver IC 15 becomes close to the wall surface 41a. In this way, the laser diode array 14 and the driver IC 15 are arranged at positions on the substrate 11 close to each other. Then, the surface emitting semiconductor laser elements of the laser diode array 14 and the wiring (a part of the electrode pattern) to which the driver IC 15 is electrically connected are electrically connected to each other, respectively, with the wires 22.

The second embodiment configured as described above takes the following operations and effects in addition to the operations and effects taken by the first embodiment.
Cross talk between adjacent transmission lines can be reduced in the optical module mounting the driver IC 15 on the substrate 11 by the flip chip mounting. In addition, the transmission lines for transmitting signals between the surface emitting semiconductor laser elements of the laser diode array 14 and the driver IC 15 are each composed of the wiring on the substrate 11 to which the drive IC 15 is electrically connected and the wires 22 in this case.
Because the wall surfaces 41a of the recess section 41 are set to be substantially vertical, the laser diode array 14 and the driver IC 15 can be arranged to be close to each other, and the wires 22 can be shortened. Hereby, crosstalk between adjacent ones of the wires 22 can be reduced, and high speed parallel optical transmission can be realized.

### Third Embodiment

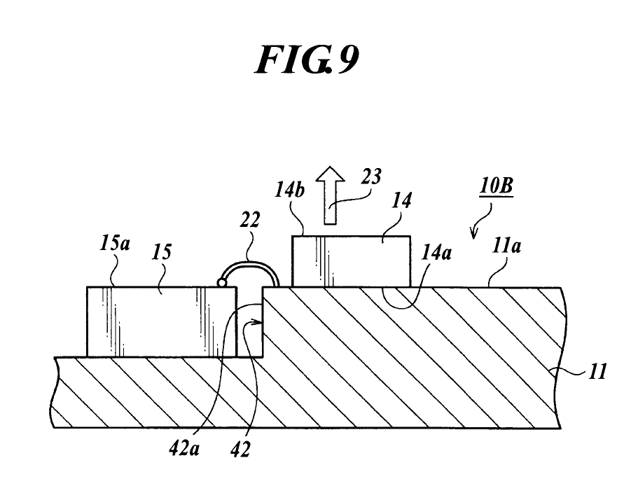

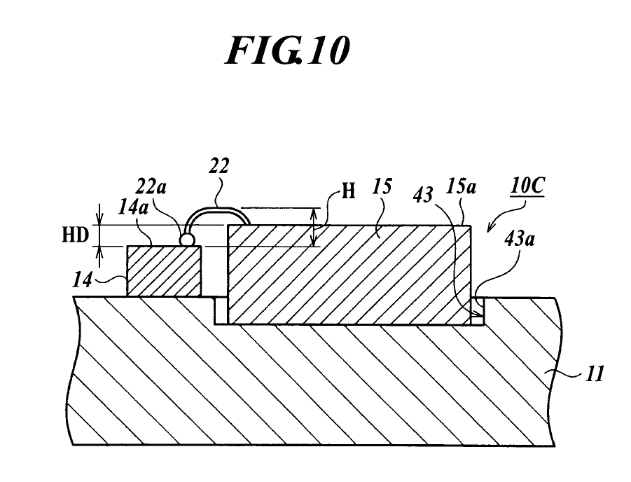

An optical module 10B according to a third embodiment is described with reference to FIG. 9.

In the first and second embodiments, each of the surface emitting semiconductor laser elements of the laser diode array 14 is a vertical cavity surface emitting laser (VCSEL), emitting a light (optical signal 23) from the surface 14a side into the direction perpendicular to the substrate surface. On the other hand, each of the surface emitting semiconductor laser elements of the laser diode array 14 used in the optical module 10B is a back surface light emitting type VCSEL, emitting a light (optical signal 23) from the back surface 14b side into the direction perpendicular to the substrate surface.

The features of the optical module 10B exist in the following configuration.
Each of the surface emitting semiconductor laser elements of the laser diode array 14 is a back surface light emitting type VCSEL.
As shown in FIG. 9, the laser diode array 14 including the surface emitting semiconductor laser elements, is mounted on the substrate 11 by the flip chip mounting.
The driver IC 15 is arranged in a recess section 42 formed on the substrate 11 in such a manner that the surface 15a of the driver IC 15 and the surface 11a of the substrate 11 are substantially on a same level to minimize the wire lengths.
The driver IC 15 and a plurality of pieces of wiring (a part of the electrode pattern) to which the surface emitting semiconductor laser elements of the laser diode array 14 are electrically connected, on the substrate 11 are electrically connected to each other, respectively, with the wires 22.

The other configuration is similar to that of the optical module 10 of the first embodiment, described above.

By such a configuration, the lengths of the wires (transmission lines) 22 for transmitting signals between the surface emitting semiconductor laser elements of the laser diode array 14 and the driver IC 15, respectively, are minimized.

The whole of the driver IC 15 is housed in the recess section 42 of the substrate 11 to be mounted on the bottom surface of the recess section 42 by being adhered thereto with, for example, a die attach adhesive. The recess section 42 is a rectangular hole having substantially vertical wall surfaces 42a and a depth substantially same as the height of the driver IC 15. The driver IC 15 is arranged in the recess section 42 in such a way that one of the end faces becomes close to one of the wall surfaces 42a. On the other hand, the laser diode array 14 is mounted on the electrode pattern of the substrate 11 in such a way that one of the end faces becomes to be close to the wall surface 42a. Then, the wiring (a part of the electrode pattern) to which the surface emitting semiconductor laser elements of the laser diode array 14 are electrically connected and the driver IC 15 are electrically connected to each other, respectively, with the wires 22.

The third embodiment configured as described above takes the following operations and effects in addition to the operations and effects taken by the first embodiment described above.
Cross talk between adjacent transmission lines can be reduced in the optical module mounting the laser diode array 14 on the substrate 11 by the flip chip mounting, which laser diode array 14 includes the surface emitting semiconductor laser elements, each being a back surface light emitting type VCSEL. In addition, the transmission lines for transmitting signals between the surface emitting semiconductor laser elements of the laser diode array 14 and the driver IC 15 are composed of a plurality of pieces of wiring on the substrate 11 (a part of the electrode pattern), to which wiring the surface emitting semiconductor laser elements of the laser diode array 14 are electrically connected, and the wires 22, respectively, in this case.
Because the wall surfaces 42a of the recess section 42 are set to be substantially vertical, the laser diode array 14 and the driver IC 15 can be arranged to be close to each other, and the wires 22 can be shortened. Hereby, crosstalk between adjacent ones of the wires 22 can be reduced, and high speed parallel optical transmission can be realized.

### Fourth Embodiment

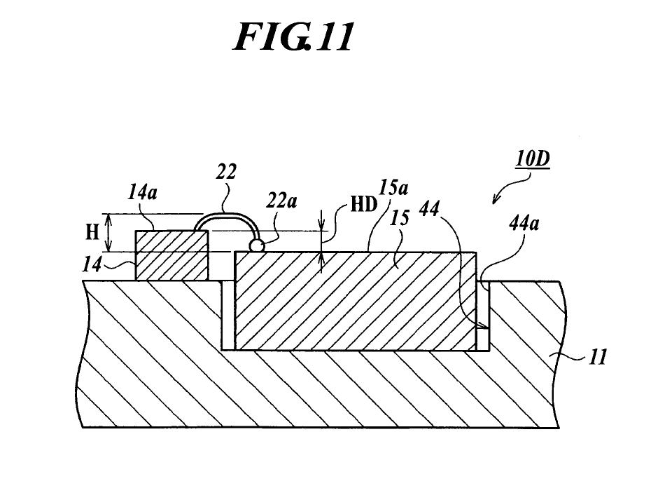

An optical module 10C according to a fourth embodiment is described with reference to FIG. 10.

In the optical module 10 of the first embodiment described above, the lengths of the wires 22 are minimized by making the surface 14a of the laser diode array 14 and the surface 15a of the drive IC 15 substantially on a same level to minimize the wire lengths. On the other hand, the features of the optical modules 10C exist in the following configuration.
The driver IC 15 is arranged in a recess section 43 formed in the substrate 11.
The electrodes on the surface 14a of the laser diode array 14 and the electrodes on the surface 15a of the driver IC 15 are electrically connected to each other in a direct manner, respectively, with the wires 22.
The surface 15a of the driver IC 15 is set to be higher than the surface 14a of the laser diode array 14 within a range in which no electrical short circuits are caused at the respective both ends of the wires 22.

The other configuration is similar to that of the optical module 10 of the first embodiment, described above.

The fourth embodiment configured as described above takes the following operation and effect in addition to the operations and effects taken by the first embodiment described above.

Each of the wire lengths can be shortened as short as possible without causing any electrical short circuits at the respective both ends of the wires 22. Hereby, cross talk between adjacent ones of the wires 22 can be reduced, and high speed parallel optical transmission can be realized.

### (Example)

In the optical module 10C described above, gold wires each having a diameter φ of 25 μm were used as the wires 22. Furthermore, the surface 15a of the drive IC 15 was set to be higher than the surface 14a of the laser diode 14 in order that HD=H−(25 μm×2), where H denoted the loop heights of the wires 22, and HD denoted the height from the surface 14a of the laser diode array 14 to the surface 15a of the driver IC 15. Balls 22a were mounted on the surface 14a of the laser diode array 14.

According to the example, the wire lengths of the wires 22 could be shortened as short as possible without causing any electrical short circuits at the respective both ends of the wires 22.

### Fifth Embodiment

An optical module 10D according to a fifth embodiment is described with reference to FIG. 11.

In the optical module 10 of the first embodiment described above, the lengths of the wires 22 are minimized by making the surface 14a of the laser diode array 14 and the surface 15a of the driver IC 15 substantially on a same level to minimize wire lengths. On the other hand, the features of the optical module 10C exist in the following configuration.
The driver IC 15 is arranged in a recess section 44 formed in the substrate 11.
The electrodes on the surface 14a of the laser diode array 14 and the electrodes on the surface 15a of the driver IC 15 are electrically connected to each other in a direct manner, respectively, with the wires 22.
The surface 14a of the laser diode array 14 is set to be higher than the surface 15a of the driver IC 15 within a range of causing no electrical short circuits at the respective both ends of the wires 22.

The other configuration is similar to that of the optical module 10 of the first embodiment.

The fifth embodiment configured as described above takes the following operation and effect in addition to the operations and effects taken by the first embodiment described above.

Each of the wire lengths can be shortened as short as possible without causing any electrical short circuits at the respective both ends of the wires 22. Hereby, crosstalk between adjacent ones of the wires 22 can be reduced, and high speed parallel optical transmission can be realized.

### (Example)

In the optical module 10D described above, gold wires each having a diameter φ of 25 micrometers are used as the wires 22. Furthermore, the surface 14a of the laser diode 14 was set to be higher than the surface 15a of the driver IC 15 in order that HD=H−(25 [μm]×2), where H denoted the loop heights of the wires 22, and HD denoted the height from the surface 14a of the laser diode array 14 to the surface 15a of the driver IC 15. Balls 22a were mounted on the surface 15a of the driver IC 15.

According to the example, the wire lengths of the wires 22 could be shortened as short as possible without causing any electrical short circuits at the respective both ends of the wires 22.

### Sixth Embodiment

The configuration of an optical module according to a sixth embodiment is similar to that of the optical module according to the first embodiment described with reference to FIGS. 1 to 7.

The optical module according to the sixth embodiment is described with reference to FIGS. 1 to 7, 12, and 13.

FIG. 1 is a perspective view showing the principal part of the optical module according to the sixth embodiment, and FIG. 2 is a sectional view of FIG. 1. FIG. 3 is a longitudinal sectional view showing the schematic configuration of the optical module. FIG. 4A is a perspective view showing the whole optical module; FIG. 4B is an enlarged view showing one of a plurality of optical fibers to be used for the optical module; and FIG. 4C is a plan view showing the connection relation of the respective surface emitting semiconductor laser elements of the laser diode array used for the optical module and a driver IC. FIG. 5 is an exploded perspective view showing the schematic configuration of the optical module; FIG. 6 is a perspective view of the optical connector unit of the optical module; and FIG. 7 is a perspective view showing a state in which an external connector (multicore ferrule type connector) is mounted in the optical connector unit of the optical module.

The optical module 10 according to the sixth embodiment is the one transmitting optical signals with the optical fibers in parallel. As shown in FIGS. 1 and 2, the optical module 10 includes the substrate 11, having an electrode pattern (not shown), a plurality of optical elements, mounted on the electrode pattern in a line, and an electronic device, mounted on the electrode pattern to be electrically connected to the optical elements.

The substrate 11 is a ceramic substrate. In the present embodiment, the optical elements are composed of the laser diode array 14, including the surface emitting semiconductor laser elements (optical elements) aligned in a line. The mark 14a in FIG. 4C denotes one of light emitting sections (aperture sections) of the surface emitting semiconductuor laser elements of the laser diode array 14. The surface emitting semiconductor laser elements as optical elements are vertical cavity surface emitting lasers (VCSELs) each emitting a light (optical signal 23) into the direction perpendicular to the substrate surface.

Furthermore, the electronic device is a driver IC 15, driving the surface emitting semiconductor laser elements of the laser diode array 14. As shown in FIGS. 1 and 2, the laser diode array 14 and the driver IC 15 are arranged on the substrate 11 at positions close to each other. To put it concretely, the laser diode array 14 is mounted on the surface 11a of the substrate 11 by being adhered thereon with, for example, a die attach adhesive. A part of the driver IC 15 is housed in the recess section 40 on the substrate 11 to be mounted on the bottom surface of the recess section 40 by being adhered thereto with, for example, a die attach adhesive. The recess section 40 is a rectangular hole having the substantially vertical wall surfaces 40a. The laser diode array 14 is arranged on the surface 11a of the substrate in such a way that an end face thereof is situated to be close to one of the wall surfaces 40a. On the other hand, the driver IC 15 is arranged on the bottom surface in such a way that one of the end faces of the driver IC 15 is situated to be close to the wall surface 40a. In this way, the laser diode array 14 and the driver IC 15 are arranged at positions on the substrate 11 close to each other. Then, the electrodes on the surface 15a of the driver IC 15 and the electrode of the respective surface emitting semiconductor laser elements on the surface 14a of the laser diode array 14 are electrically connected to each other, respectively in a direct manner, with the wires 22 (see FIGS. 1, 2, and 4C).

Namely, the driver IC 15 and the surface emitting semiconductor laser elements of the laser diode array 14 are electrically connected to each other, respectively, with the wires 22 without the wiring on the SiOB unlike the conventional technique. Hereby, the optical module 10 is adapted in order that a modulation signal may be input from the driver IC 15 to each of the surface emitting semiconductor laser elements of the laser diode array 14 through each of the bonding wires 22, and that the optical signal 23, modulated by the modulation signal, is emitted from each of the surface emitting semiconductor laser elements of the laser diode array 14. Furthermore, the driver IC 15 and the electrode pattern of the substrate 11 are electrically connected to each other with a not-shown plurality of bonding wires. The mark 22a in FIG. 4C denotes each ball mounted onto the electrode of each of the surface emitting semiconductor laser elements.

The optical module 10 furthermore includes the optical connector unit 12, the cover 13, and the two guide pins 32 as shown in FIGS. 3, 4A, and 5.

The optical connector unit 12 holds the optical fibers 16, aligned in a line (in the direction perpendicular to the paper surface in FIG. 3), as shown in FIGS. 4A to 4C and 6. The optical connector unit 12 is aligned by the active alignment in such a way that the center (core center) of each of the first facets 16a (see FIG. 4B) of the optical fibers 16 and the center of each of the light emitting sections 14a of the laser diode array 14 accord with each other, and, after that, the optical connector unit 12 is fixed on the surface 11a of the substrate 11. Hereby, the optical module 10 is adapted to optically couple each emitted light (optical signal 23) from each of the light emitting sections 14a of the laser diode array 14 to each of the first facets 16a of the optical fibers corresponding to the optical fibers 16.

Furthermore, the optical connector unit 12 has side wall sections 17 on both sides as shown in FIG. 6. The bottom surfaces 17a of both the side wall sections 17 severally contact with the surface 11a of the substrate 11 in a slidable state. The optical connector unit 12 is two-dimensionally moved on the surface 11a of the substrate 11 by the active alignment in order that the center of each of the first facets 16a of the optical fibers 16 and the center of each of the light emitting sections 14a of the laser diode array 14 may accord with each other, and after that, the bottom surfaces 17a of both the side wall sections 17 of the optical connector unit 12 are fixed to the surface 11a of the substrate 11 by adhering or the like.

Furthermore, as shown in FIG. 6, the optical connector unit 12 includes the fiber holding holes 12a, to which the optical fibers 16 are fit, which fiber holding holes 12a are aligned in a line, and the two guide pin holes 12b formed on both the sides of the fiber holding holes 12a. The two guide pins 32 are adapted to be able to fit into the two guide pin holes 12b, respectively.

The two guide pins 32 are adapted to be able to fit into the two through-holes, respectively, of the MT connector 30, which is an external connector shown in FIG. 7. By fitting the two through-holes of the MT connector 30 into the two guide pins 32, respectively, the MT connector 30 is adapted to be mounted onto the optical connector unit 12, as shown in FIG. 7, in the state in which the core center of each of the optical fibers of the multicore optical fiber (multicore tape optical fiber) 31, held by the MT connector 30, and each of the core centers of the optical fibers 16, held by the optical connector unit 12, accord with each other.

As shown in FIGS. 3, 4A, and 5, the cover 13 includes the opening 13a for mounting the optical connector unit 12 and is fixed to the substrate 11 by adhesion or the like in order to cover all the parts, such as the laser diode array 14 and the driver IC 15. The cover 13 is made of a material having high thermal conductivity, such as an alloy of copper (Cu) and tungsten (W).

Furthermore, a resin 18, such as a resin sealing agent or an adhesive, is filled in the space between a side surface of the optical connector unit 12 and the opening 13a of the cover 13 as shown in FIG. 3. A silicone gel 19, having heat conductance and insulation properties, is filled as a sealing agent in a gap (space) between the driver IC 15 and the cover 13. Furthermore, a transparent silicone gel 20 is filled in a space between first facets 16a of the optical fibers 16 and the respective light emitting sections 14a of the laser diode array 14 as a sealing agent.

The sixth embodiment, configured as described above, takes the following operations and effects.
Because the laser diode array 14 and the driver IC 15 are arranged on the substrate 11 at positions close to each other, the lengths of the transmission lines connecting the surface emitting semiconductor laser elements of the laser diode array 14 and the driver IC 15 electrically become short, and crosstalk between adjacent transmission lines can be reduced. Hereby, high speed parallel optical transmission can be realized.
The sixth embodiment is configured in order that the optical fibers 16 and the surface emitting semiconductor laser elements of the laser diode array 14 may be optically coupled, respectively, by the active alignment by performing two-dimensional position adjustment of the optical connector unit 12 on the substrate 11. Namely, by the active alignment, the center of each of the first facets 16a of the optical fibers 16 and the center of each of the light emitting sections 14a of the laser diode array 14 accord with each other. Consequently, the SiOB for performing the passive alignment becomes unnecessary unlike the conventional technique mentioned above, and the laser diode array 14 and the driver IC 15 can be arranged on the substrate 11 at positions close to each other. Hereby, the lengths of the wires 22 (transmission line lengths), connecting the surface emitting semiconductor laser elements of the laser diode array 14 and the driver IC 15 to each other electrically, can be shortened, and crosstalk between adjacent transmission lines can be reduced.
Because the driver IC 15 and the surface emitting semiconductor laser elements of the laser diode array 14 are electrically connected to each other in a direct manner with the wires 22, respectively, the wire lengths L (see FIG. 2) of the wires 22 become short. Hereby, crosstalk between adjacent wires can be reduced in the optical module mounting the driver IC 15 and the laser diode array 14 thereon by the wire bonding mounting.

### (Example)

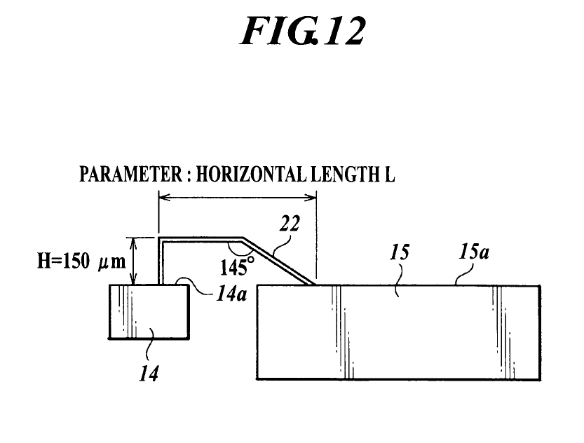

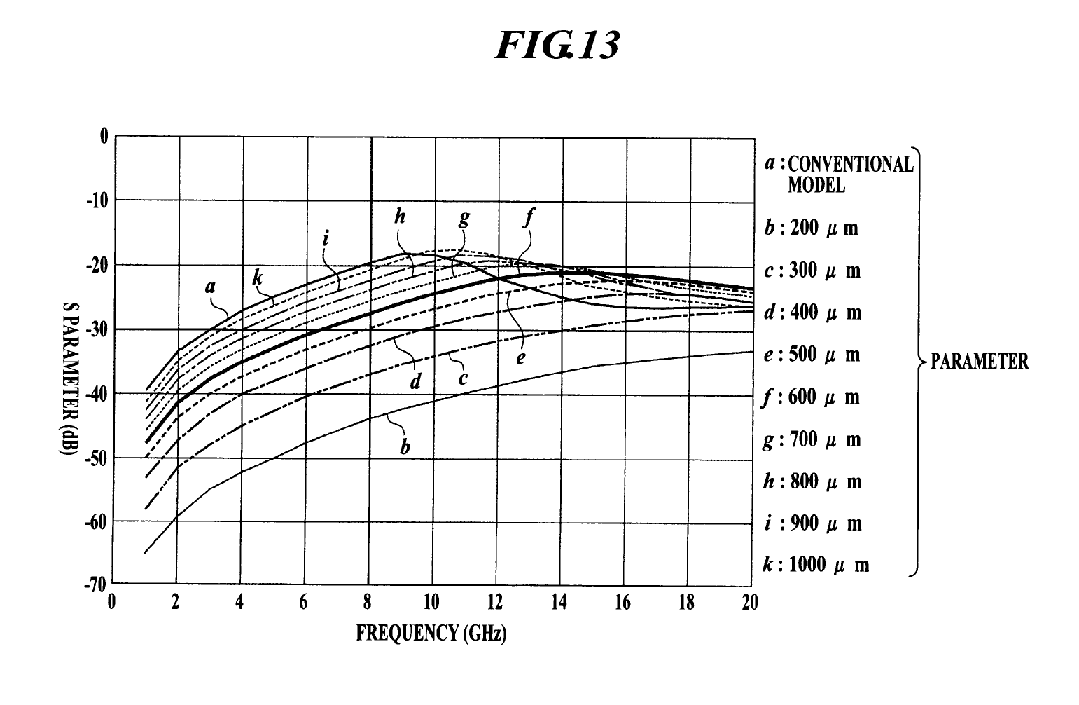

In the sixth embodiment, the lengths L of the wires (wire lengths) of the wires 22 in the horizontal direction of the wires were severally set to 500 micrometers or less. In the present example, the wire of the shape shown in FIG. 12 was used as each of the wires 22. Furthermore, the surface 14a of the laser diode array 14 and the surface 15a of the driver IC 15 were set to be the same heights. Furthermore, the pitches between the wires 22 were set to be 250 micrometers.

The graph of FIG. 13 shows the results of comparison of crosstalk between adjacent wires (between adjacent channels) in a conventional model and a proposed model. The conventional model is the optical module here, as the conventional technique mentioned above, which is configured in such a way that a plurality of optical elements are connected with wiring on an SiOB and wires, and that the wiring is connected to an electronic device with wires. The proposed model is the optical module 10 described in the sixth embodiment. The abscissa axis of FIG. 13 indicates the frequency (GHz) of the modulation signals to be transmitted from the driver IC to each of the surface emitting semiconductor laser elements through the wires 22, and the ordinate axis indicates scattering parameters (S parameters) expressing the crosstalk components between channels, respectively.

In the graph of FIG. 13, a curved line indicates an S parameter when the frequency of a modulation signal in the conventional model is changed. From the curved line a, it is known that the crosstalk between adjacent wires (channels) cannot be suppressed to be 30 decibels or less in a transmission band exceeding 3 GHz in the conventional model.

Furthermore, in the graph of FIG. 13, the S parameters when the frequency of the modulation signal is changed in the case where the lengths L (wire lengths) in the horizontal direction are changed to be 200 micrometers, 300 micrometers, 400 micrometers, 500 micrometers, 600 micrometers, 700 micrometers, 800 micrometers, 900 micrometers, and 1000 micrometers in the optical module 10 described above are shown by a curved line b, a curved line c, a curved line d, a curved line e, a curved line f, a curved line g, a curved line h, a curved line i, and a curved line k, respectively. From the curved lines b, c, d, and e, it is known that crosstalk between adjacent wires (channels) in a transmission band up to 8 GHz, which is necessary for the transmission of a signal of 10 Gbit/s, can be suppressed to be 30 decibels or less by making the lengths L in the horizontal direction of the wires L 500 micrometers or less.

### Seventh Embodiment

The configuration of an optical module according to a seventh embodiment is similar to the one of the optical module according the second embodiment described with reference to FIG. 8.

The optical module 10A according to the seventh embodiment is described with reference to FIG. 8.

In the sixth embodiment described above, the driver IC 15 is mounted on the electrode pattern of the substrate 11 by the wire bonding. On the other hand, in the optical module 10A according to the seventh embodiment, as shown in FIG. 8, the driver IC 15 is mounted on the electrode pattern of the substrate 11 by the flip chip mounting. The whole of the laser diode array 14 is hosed in the recess section 41 on the substrate 11 to be mounted on the bottom surface of the recess section 41 by being adhered thereto with, for example, a die attach adhesive. The recess section 41 is a rectangular hole having the substantially vertical wall surfaces 41a and substantially the same depth as the height of the laser diode array 14. The laser diode array 14 is arranged in the recess section 41 in such a way that one of the end faces is situated at a position near to one of the wall surfaces 41a. On the other hand, the driver IC 15 is mounted on the electrode pattern of the substrate 11 in such a way that one of the end faces is situated at a position close to the wall surface 41a. In this way, the laser diode array 14 and the driver IC 15 are arranged at positions on the substrate 11 close to each other. Then, the surface emitting semiconductor laser elements of the laser diode array 14 and the wiring (a part of the electrode pattern), to which the driver IC 15 is electrically connected, are electrically connected to each other, respectively, with the wires 22.

The other configuration is similar to that of the optical module 10 of the sixth embodiment.

The seventh embodiment configured as described above takes the following operations and effects in addition to the operations and effects taken by the sixth embodiment.
The transmission lines are composed of the wires 22 by which the surface emitting semiconductor laser elements of the laser diode array 14 and the driver IC 15 are electrically connected with each other, and the wiring to which the driver IC 15 is electrically connected. Hence, the lengths of the transmission lines are shortened. Hereby, cross talk between adjacent transmission lines can be reduced in the optical module mounting the driver IC 15 on the electrode pattern of the substrate 11 by the flip chip mounting.
Crosstalk between adjacent wires (channels) can be suppressed to be 30 decibels or less at the time of transmission in a transmission band up to 8 GHz by making the lengths of the transmission lines 500 micrometers or less.

### Eighth Embodiment

The configuration of an optical module according to an eighth embodiment is similar to that of the optical module according to the third embodiment described with reference to FIG. 9.

The optical module 10B according to the eighth embodiment is described with reference to FIG. 9.

In the sixth and seventh embodiments described above, each of the surface emitting semiconductor laser elements of the laser diode array 14 is a vertical cavity surface emitting laser (VCSEL), emitting a light (optical signal 23) from the surface side into the direction perpendicular to the substrate surface. On the other hand, each of the surface emitting semiconductor laser elements of the laser diode array 14 used in the optical module 10B is a back surface light emitting type VCSEL, emitting a light (optical signal 23) from the back surface side into the direction perpendicular to the substrate surface.

In the optical module 10B, as shown in FIG. 9, the laser diode array 14 is mounted on the electrode pattern of the substrate 11 by the flip chip mounting. The whole of the driver IC 15 is housed in a recess section 42 on the substrate 11 and is mounted on the bottom surface of the recess section 42 by being adhered thereto with, for example, a die attach adhesive. The recess section 42 is a rectangular hole having the substantially vertical wall surfaces 42a and substantially the same depth as the height of the driver IC 15. The driver IC 15 is arranged in the recess section 42 in such a way that one of the end faces of the driver IC 15 is situated close to one of the wall surfaces 42a. On the other hand, the laser diode array 14 is mounted on the electrode pattern of the substrate 11 in such a way that one of the end surfaces of the laser diode array 14 is situated to be close to the wall surface 42a. In this way, the laser diode array 14 and the driver IC 15 are arranged at positions on the substrate 11 close to each other. Then, the pieces of wiring (a part of the electrode pattern), to which the surface emitting semiconductor laser elements of the laser diode array 14 is electrically connected, and the driver IC 15 are electrically connected to each other, respectively, with the wires 22.

The other configuration is similar to that of the optical module 10 of the sixth embodiment, described above.

The eighth embodiment configured as described above takes the following operations and effects in addition to the operations and effects taken by the first embodiment described above.

Cross talk between adjacent transmission lines can be reduced in the optical module mounting the laser diode array 14 on the substrate 11 by the flip chip mounting, which laser diode array 14 includes the surface emitting semiconductor laser elements, each being a back surface light emitting type VCSEL.

In addition, the present invention can be embodied by changing as follows.
The optical modules 10, 10A, 10B, 10C, and 10D, configured as the transmission side optical modules, have been described in the respective embodiments described above, but the present invention is not limited to the transmission side optical modules. A photodiode array having a plurality of photodiode elements (optical elements) aligned in a line may be used in each of the optical modules 10, 10A, 10B, 10C, and 10D in place of the laser diode array 14. Then, the present invention can also be applied to an optical module configured as a reception side optical module using an amplifying IC having the transimpedance amplifier (TIA) function converting the output current of each photodiode into a voltage to amplify the converted voltage in place of the driver IC 15.
Furthermore, the present invention can also be applied to an optical module mounting a plurality of surface emitting semiconductor laser elements (optical elements) aligned in a line in place of the laser diode array 14, or an optical module mounting a plurality of photodiodes (optical elements) aligned in a line in place of the photodiode array.

### INDUSTRIAL APPLICABILITY

The present invention can be used in the field of optical communication, and can be applied to an optical module transmitting optical signals in parallel with optical fibers.

### DESCRIPTION OF REFERENCE NUMERALS

10, 10A, 10B, 10C, 10D: optical module
11: substrate
11a: surface
12: optical connector unit
13: cover
14: laser diode array
14a: surface
15: driver IC (electronic device)
15a: surface
16: optical fiber
16a: one end
22: wire
23: optical signal
30: multicore optical fiber connector (MT connector)
31: multicore optical fiber (multicore tape optical fiber)
40, 41, 42, 43, 44: recess section
40a, 41a, 42a, 43a, 44a: wall surface

1-18. (canceled)

19. An optical module that transmits optical signals through a plurality of optical fibers in parallel, the optical module comprising:
a substrate including an electrode pattern;
a plurality of optical elements mounted on the electrode pattern of the substrate; and
an electronic device mounted on the electrode pattern of the substrate and electrically connected to the optical elements, wherein
the optical elements and the electronic device are arranged on the substrate close to each other such that lengths of a plurality of transmission lines each transmitting a signal between each of the optical elements and the electronic device are minimized.

20. The optical module according to claim 19, further comprising:
an optical connector unit that holds the optical fibers and is fixed on the substrate at a position where each of the optical fibers and each of the optical elements are optically coupled to each other, wherein
the position of the optical connector unit can be ajusted two-dimensionally on a plane of the substrate.

21. The optical module according to claim 19, wherein
the substrate includes a recess section formed thereon,
the electronic device is arranged in the recess section formed on the substrate in such a manner that surfaces of the optical elements and a surface of the electronic device are substantially on a same level, and
the surfaces of the optical elements and the surface of the electronic device are electrically connected to each other with a plurality of wires as the transmission lines in a direct manner.

22. The optical module according to claim 21, wherein
the recess section includes substantially vertical wall surfaces;
the optical elements are arranged on the substrate along one of the wall surfaces at positions close to the one of the wall surfaces; and
the electronic device is arranged in the recess section at a position close to the one of the wall surfaces.

23. The optical module according to claim 19, wherein
the electronic device is mounted on the substrate by flip chip mounting;
the optical elements are arranged in the recess section formed on the substrate in such a manner that surfaces of the optical elements and a surface of the substrate are substantially on a same level; and
the surfaces of the optical elements and a wiring on the substrate to which wiring the electronic device is electrically connected are electrically connected to each other with a plurality of wires.

24. The optical module according to claim 19, wherein
the optical elements are surface emitting semiconductor laser elements each emitting a light from a back side thereof;
the optical elements are mounted on the substrate by flip chip mounting;
the electronic device is arranged in a recess section formed on the substrate in such a manner that a surface of the electronic device and a surface of the substrate are substantially on a same level to minimize wire lengths; and
the electronic device and a wiring on the substrate to which the optical elements are electrically connected are electrically connected to each other with a plurality of wires.

25. The optical module according to claim 19, wherein
the electronic device is arranged in a recess section formed on the substrate;
surfaces of the optical elements and a surface of the electronic device are electrically connected to each other with a plurality of wires as the transmission lines in a direct manner; and
the surface of the electronic device is set to be higher than the surfaces of the optical elements within a range in which no electrical short circuits are caused at both ends of each of the wires.

26. The optical module according to claim 19, wherein
the electronic device is arranged in a recess section formed on the substrate;
surfaces of the optical elements and a surface of the electronic device are electrically connected to each other with a plurality of wires as the transmission lines in a direct manner; and
the surfaces of the optical elements are set to be higher than the surface of the electronic device within a range in which no electrical short circuits are caused at both ends of each of the wires.

27. The optical module according to claim 19, wherein
the optical elements are surface emitting semiconductor laser elements,
the electronic device is a driver integrated circuit that drives the surface emitting semiconductor laser elements, and
the optical module is a transmission side optical module that transmits the optical signals output from the surface emitting semiconductor laser elements to an outside through the optical fibers in parallel.

28. The optical module according to claim 19, wherein
the optical elements are photodiodes,
the electronic device is an amplifying integrated circuit that converts output currents of the photodiodes into voltages and amplifies the voltage, and
the optical module is a reception side optical module that receives the optical signals from an outside through the optical fibers in parallel and converts received optical signals into electric signals with the photodiodes.

29. An optical module that transmits optical signals through a plurality of optical fibers in parallel, the optical module comprising:
a substrate including an electrode pattern;
a plurality of optical elements mounted on the electrode pattern of the substrate; and
an electronic device mounted on the electrode pattern of the substrate and electrically connected to the optical elements, wherein
the optical elements and the electronic device are arranged at positions close to each other on the substrate.

30. The optical module according to claim 29, further comprising:
an optical connector unit that holds the optical fibers and is fixed on the substrate at a position where each of the optical fibers and each of the optical elements are optically coupled to each other, wherein
the position of the optical connector unit can be adjusted two-dimensionally on a plane of the substrate.

31. The optical module according to claim 29, wherein the electronic device and the optical elements are electrically connected to each other with a plurality of wires in a direct manner.

32. The optical module according to claim 31, wherein each of lengths in horizontal directions of the wires is set to be 500 micrometers or less.

33. The optical module according to claim 29, wherein
the electronic device is mounted on the substrate by flip chip mounting, and
the optical elements and a wiring on the substrate to which the electronic device is electrically connected are electrically connected to each other with a plurality of wires.

34. The optical module according to claim 33, wherein lengths of a plurality of transmission lines composed of the wires and the wiring which electrically connect the optical elements and the electronic device are set to be 500 micrometers or less.

35. The optical module according to claim 29, wherein
the optical elements are surface emitting semiconductor laser elements,
the electronic device is a driver integrated circuit that drives the surface emitting semiconductor laser elements,
and the optical module is a transmission side optical module that transmits optical signals output from the surface emitting semiconductor laser elements to an outside through the optical fibers in parallel.

36. The optical module according to claim 29, wherein
the optical elements are photodiodes,
the electronic device is an amplifying integrated circuit that converts output currents of the photodiodes into voltages and amplifies the voltages, and
the optical module is a reception side optical module that receives optical signals from an outside through the optical fibers in parallel, and converts the received optical signals into electric signals with the photodiodes.
